(19) United States
(12) Patent Application Publication
(10) Pub. No.: US 2002/0074140 A1
(43) Pub. Date: Jun. 20, 2002

(54) SCREENING HOUSE FOR MICROWAVE CIRCUITS

(76) Inventors: WOLFGANG KUSCHKE, OPPENWEILER (DE); HARDIAL SINGH GILL, BACKNANG (DE); WILLIBALD KONRATH, WEISSACH (DE)

Correspondence Address: STRIKER STRIKER & STENBY, 103 EAST NECK ROAD, HUNTINGTON, NY, 11743

(21) Appl. No.: 09/095,397

(22) Filed: Jun. 10, 1998

(30) Foreign Application Priority Data
Jul. 5, 1997 (DE) 19728839.1-34

(51) Int. Cl. H05K 9/00

(52) U.S. Cl. 174/35 R; 439/108

(57) ABSTRACT

A screening housing for microwave circuits has a housing body having an interior and open at least at one side, a cover closing the interior of the housing, and means forming a plurality of chambers provided for accommodating of individual circuit units and screened from one another, the means including a substrate and applied on an inner side of the cover and a plurality of webs which are formed on the substrates so that when the cover closes the housing the webs form separating walls between the chambers.

### BACKGROUND OF THE INVENTION

The present invention relates to a screening housing for microwave circuits. More particularly, it relates to such a screening housing with a plurality of chambers which are screened from one another and which accommodate circuit units to be oppositely electromagnetically coupled.

Conventionally, a multi-chamber housing which must accommodate a plurality of microwave circuits screened from one another in a high frequency type manner is produced by milling of the individual chambers from a massive metal body. One of such screening housings is disclosed for example in the German document DE 35 04 726 C1. The manufacture of such a housing with several high frequency-tight chambers is very expensive.

Another German patent document DE 43 19 965 A1 discloses a housing with separating joints provided for example between the cover and the housing walls, and sealing profiles inserted in the separating joints and composed of an elastic polymer with embedded metal particles.

### SUMMARY OF THE INVENTION

Accordingly, it is an object of the present invention to provide a screening housing of the above mentioned type which avoids the disadvantages of the prior art.

More particularly, it is an object of the present invention to provide a screening housing of the above mentioned general type which can be produced with lower expenses.

In keeping with these objects and with others which will become apparent hereinafter, one feature of present invention resides, briefly stated in a screening housing for microwave circuits, in which on the inner side of the cover which closes the housing, a substrate is arranged of a polymer with embedded metal particles, and webs are provided on the substrate which together with the placed cover form the separating walls between the chambers.

The substrate with the webs which form the chambers can be cast on the inner side of the cover. Any structure of the substrate with webs can be made without high expenses. The substrate from a polymer with the embedded metal particles not only performs a screening function, but also dampens simultaneously undesirable resonance frequency in the chambers.

The material of the housing, in particular polymer with the embedded metal particles can be a silicone mass filled with iron powder.

The novel features which are considered as characteristic for the present invention are set forth in particular in the appended claims. The invention itself, however, both as to its construction and its method of operation, together with additional objects and advantages thereof, will be best understood from the following description of specific embodiments when read in connection with the accompanying drawings.

### BRIEF DESCRIPTION OF THE DRAWINGS

FIG. 1 is a view showing an open screening housing with its interior, in accordance with the present invention; and

FIG. 2 is a view showing the same screening housing from an inner side of its cover.

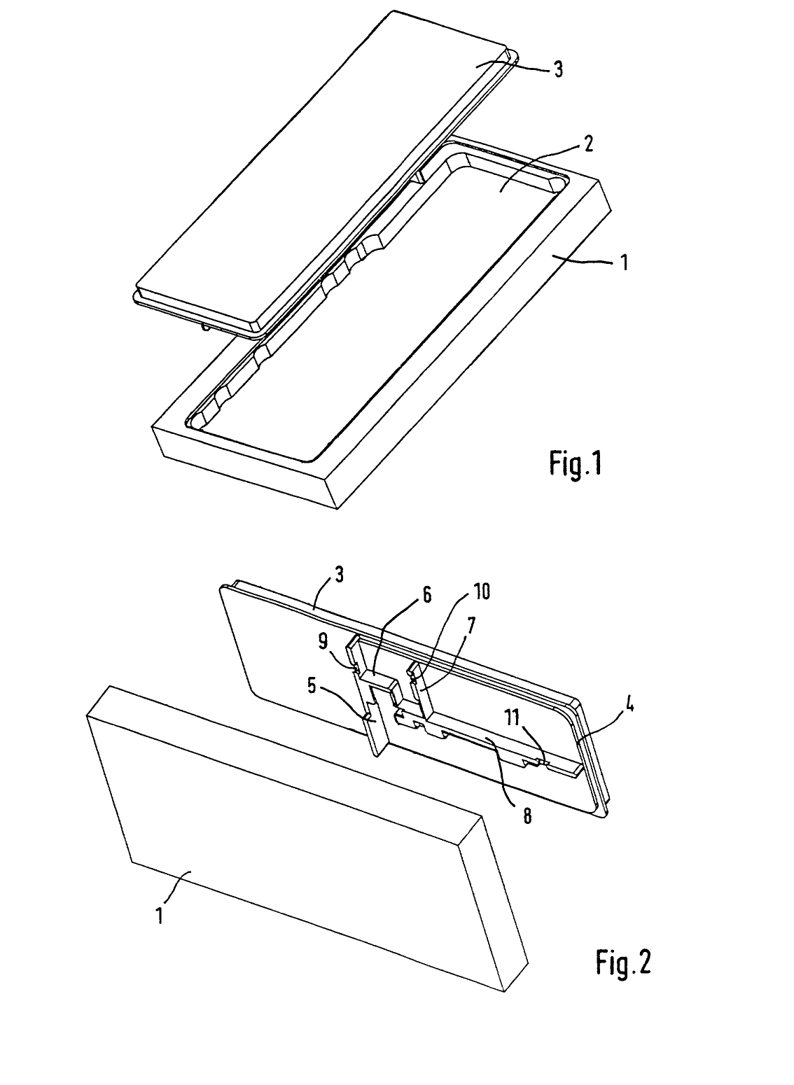

### DESCRIPTION OF PREFERRED EMBODIMENTS

A screening housing for microwave circuits in accordance with the present invention is identified as a whole with reference numeral 1. The screening housing has a single large chamber 2 which can be produced for example by milling from a metal block. The chamber 2 serves for receiving of microwave circuits which must be screened electromagnetically from outside. The housing 1 is closed with a cover 3.

The separating joints between the housing walls and the cover must be sealed so that no electromagnetic energy can escape outwardly. Several subunits which must be screened magnetically from one another are usually located in such a screening housing. For this purpose, several chambers for receiving individual circuit unit which must be screened electromagnetically from one another are provided in the interior of the housing 1.

FIG. 2 shows how the chambers are formed in the screening housing 1, and a perspective view of the inner side of the housing cover 3 is illustrated. A substrate 4 composed of a polymer with embedded metal particles is arranged on the inner side of the cover 3. The substrate 4 for example is composed of a silicone mass which is filled with iron powder.

Several webs 5, 6. 7, 8 are provided on the face of the substrate 4 which faces toward the interior of the housing 1. When the cover 3 is placed on the housing, the separating walls 5, 6, 7, 8 together with the cover 3 form the individual chambers inside the screening housing. As shown in the embodiment of FIG. 2, the webs 5, 6, 7, 8 can have an arbitrarily complicated structure.

The substrate 4 with the webs 5, 6, 7, 8 can be manufactured in a simple manner by casting with a mold on the inner side of the cover 3. The webs 5, 6, 7, 8 abut in a form-locking manner against the bottom of the chamber 2 when the cover 3 is placed on the housing. Additionally, they can be provided with throughgoing openings 9, 10, 11 for connecting conductors between the individual circuit units.

The webs 5, 6, 7, 8 which are composed of polymer with embedded metal particles have not only the function of screening walls but also dampen simultaneously the undesired resonance frequencies in the chamber.

It will be understood that each of the elements described above, or two or more together, may also find a useful application in other types of constructions differing from the types described above.

While the invention has been illustrated and described as embodied in screening housing for microwave circuits, it is not intended to be limited to the details shown, since various modifications and structural changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

What is claimed as new and desired to be protected by Letters Patent is set forth in the appended claims.

1. A screening housing for microwave circuits, comprising a housing body having an interior and open at least at one side: a cover closing said interior of said housing; and means forming a plurality of chambers provided for accommodating of individual circuit units and screened from one another, said means including a substrate and applied on an inner side of said cover and a plurality of webs which are formed on said substrate so that when said cover closes said housing said webs form separating walls between said chambers.

2. A screening housing as defined in claim 1, wherein said housing body is composed of an electromagnetic energy screening material.

3. A screening housing as defined in claim 1, wherein said substrate is composed of a polymer with embedded metal particles.

4. A screening housing as defined in claim 3, wherein said substrate is composed of a silicone mass with embedded metal powder.

5. A screening housing as defined in claim 1, wherein said substrate and said webs are formed of one piece with one another.

6. A screening housing as defined in claim 5, wherein said substrate and said webs are composed of the same material.

7. A screening housing for microwave circuits, comprising a housing body having an interior and open at least at one side; a cover closing said interior of said housing; and means forming a plurality of chambers provided for accommodating of individual circuit units and screened from one another, said means including a composed of a polymer with embedded metal particles and applied on an inner side of said cover and a plurality of webs which are formed on said substrates so that when said cover closes said housing said webs form separating walls between said chambers.
